(19) United States
(12) Patent Application Publication
(10) Pub. No.: US 2024/0260470 A1
(43) Pub. Date: Aug. 1, 2024

(54) THERMOELECTRIC MODULE

(71) Applicant: DOUBLE CHECK LTD., BNEI BRAK (IL)

(72) Inventors: ISAAC STEINER, TEL AVIV (IL); ALEX GUREVICH, PETAH TIKVA (IL)

(21) Appl. No.: 18/565,913

(22) PCT Filed: Jun. 5, 2022
(86) PCT No.: PCT/IL2022/050597

§ 371 Date: Nov. 30, 2023

(30) Foreign Application Priority Data
Jun. 10, 2021 (IL) 283878

(51) Int. Cl. H10N 10/13; H10N 10/01; H10N 10/17

(52) U.S. Cl. CPC H10N 10/13; H10N 10/01; H10N 10/17

(57) ABSTRACT

A thermoelectric module (TEM) for cooling and power generation applications. The TEM includes a pair of substrates, where one or more of the substrates is a vapor chamber. The TEM further includes a plurality of electrically conductive contacts disposed on opposing faces of the pair of substrates. A plurality of thermoelectric legs interposed between the pair of substrates, each of the plurality of conductive contacts connecting thermoelectric legs to each other in series and wherein each of the thermoelectric legs has a first end connected to one of the conductive contacts of one of the substrates and a second end connected to one of the conductive contacts of the other of the substrates.

### FIELD OF THE INVENTION

The present invention relates to thermoelectric modules (TEMs).

### BACKGROUND OF THE INVENTION

A thermoelectric module (TEM), also called a thermoelectric cooler or Peltier cooler, is a semiconductor-based electronic component that functions as a small heat pump, moving heat from one side of the device to the other. The TEM operates based on a principle known as the Peltier effect. Thermoelectric modules are also sometimes used to generate electricity by using a temperature difference between the two sides of the module. TEM device providing direct conversion of electrical power to cooling without additional materials like freon in conventional cooling systems. By applying a low voltage DC power source to a TEM, heat will be moved through the module from one side to the other. One module face, therefore, will be cooled while the opposite face simultaneously is heated. This phenomenon may be reversed; a change in the polarity (plus and minus) of the applied DC voltage will cause heat to be moved in the opposite direction. Consequently, a thermoelectric module may be used for both heating and cooling.

Referring to FIG. 1, illustrates a typical thermoelectric module (TEM). The TEM 10 includes several doped semiconductor elements 12 that are connected electrically in series and thermally in parallel in between two stiff ceramic plates 14. The doped semiconductor elements 12 may also be referred to as thermoelectric legs. The doped semiconductor elements 12 include both p-type elements and n-type elements. The doped semiconductor elements are connected in series through layers of solder and copper conductors pattern 16 between the doped semiconductor elements 12 and the ceramic plates 14. The several semiconductor elements 12 are creating the Peltier effect when a current is applied to the TEM 10. The TEM 10 is assembled as a unit. The ceramic plates 14 are used to provide rigidity for the TEM 10, since the semiconductor elements 12 are not attached to each other. The ceramic plates 14 are typically about 0.2 mm to 0.6 mm thick. The TEM 10 is typically assembled and then integrated into a larger cooling system.

Thermal conductivity of base plates/substrates 14 of thermoelectric modules 10 effects on the performance of module 10 for example in efficiency, temperature differential, cooling power and power generation efficiency. Presently some types of ceramics are used as a material of based plate. Most common material is alumina Al₂O₃ with thermal conductivity of 30 W/(m*K). With the goal to improve performance another ceramics AlN with thermal conductivity of 180 W/(m*K) is used. Effect of substrate material on performances of thermoelectric modules is shown on the FIG. 2, there is shown cooling power in watts and coefficient of performance (COP) versus the element length in millimeters of the following materials COP of ideal material 19, COP of aluminum nitride (AlN) 18, COP of alumina (aluminum oxide) (Al₂O₃) 23 in addition there is shown also the Qc of ideal material 20, Qc of AlN 21 and Qc of Al₂O₃ 22 where all the materials operates with current of two Amperes. COP is presented by cooling power to the input power ratio which is a measure of performance of cooling devices. The AlN has thermal conductivity higher than that for the Al₂O₃.

Further improvement can be reached by using of materials with higher thermal conductivity. The highest thermal conductivity is provided by special heat transfer devices: heat pipes having effective thermal conductivity up to 100,000 W/(m*K). Another heat transfer device, vapor chamber operating on the same principle like heat pipes but having a flat plate shape is a preferable solution for high thermally conductive substrate of thermoelectric module.

Vapor Chambers are heat conducting elements operated by Heat Pipe technology and are characterized by extremely high thermal conductivity. A heat pipe is a heat-transfer device that combines the principles of both thermal conductivity and phase transition to effectively transfer heat between two solid interfaces. The vapor chamber is used for example with a TEM in an integrated chip (IC) cooling system. Referring to FIG. 3 illustrates a cooling system 28 using the TEM 10. An integrated chip (IC) 29, such as a microprocessor, that has a high operating temperature and requires heat removal. Mounted on top of the IC 29 is a vapor chamber 30, which provides a uniform temperature at the cold side of the TEM 10. A first thermal interface material such as but not limited to grease (not shown), is used to fill gaps and form a junction between the vapor chamber 30 and the TEM 10. A heat sink 31 is mounted over the hot side of the TEM 10. A second thermal interface material fills gaps and forms a junction between the heat sink 31 and the TEM 10. The cooling system 28 draws heat from the IC 29 and into the vapor chamber 30, which evenly distributes the heat over its surface. By applying a low voltage DC power source 27 to TEM 10, heat will be moved through the module from one side to the other. The TEM 10 draws the heat away from the vapor chamber 30 and into the heat sink 31, where the heat is vented into the atmosphere. Thermoelectric module couple to a heat sink and a vapor chamber is addressed for example in US application number US20060000500.

Cooling or heating power generated on the contacts between copper conductors 16 and thermoelectric legs 12 is conducted to object such as but not limited to heat sink 26 and vapor chamber 24 through the ceramic plates 14. Due to relatively low thermal conductivity of ceramics, temperature difference on the ceramic plates 14 is significant. This effect reduces performance of thermoelectric modules.

One of the objects of the present invention is to provide one or more vapor chambers as integrated part of a TEM replacing regular ceramics substrates. Use of Vapor Chamber as substrate plate of thermoelectric module also allow to enlarge rate of temperature change provided by the TEM allowing faster temperature cycles and more precise temperature control.

### SUMMARY OF THE INVENTION

The present invention relates to thermoelectric modules (TEMs).

In accordance with an embodiment of the present invention there is provided a thermoelectric module (TEM) for cooling and power generation applications. The TEM includes a pair of substrates, where at least one or more of the substrates is a vapor chamber. The TEM further includes a plurality of electrically conductive contacts disposed on opposing faces of the pair of substrates. A plurality of thermoelectric legs interposed between the pair of substrates, each of the plurality of conductive contacts connecting thermoelectric legs to each other in series and wherein each of the thermoelectric legs has a first end connected to one of the conductive contacts of one of the substrates and a second end connected to one of the conductive contacts of the other of the substrates.

In another aspect of the present invention there is provided a method for forming a thermoelectric module (TEM) that includes, coupling multiple thermoelectric legs to a pair of thermally conductive substrates such that the multiple thermoelectric legs are interposed between the pair of substrates. Coupling electrically conductive contacts to the pair of substrates that said electrically conductive contacts are disposed on opposing faces of the pair of substrates. coupling electrically conductive contacts to said multiple thermoelectric legs so that the thermoelectric legs are connected to each other in series and each of said thermoelectric legs has a first end connected to one of the conductive contacts of one of the substrates and a second end connected to one of the conductive contacts of the other of the substrates, wherein at least one substrate of the pair of thermally conductive substrates is a vapor chamber.

### BRIEF DESCRIPTION OF THE DRAWINGS

The invention may be understood upon reading of the following detailed description of non-limiting exemplary embodiments thereof, with reference to the following drawings, in which:

FIG. 1 illustrates schematically a typical thermoelectric module (TEM);

FIG. 2 a graph describing the effect of ceramics material on performance of thermoelectric cooling modules;

FIG. 3 illustrates schematically a cooling system using the TEM;

FIG. 4 illustrates schematically a thermoelectric module in accordance with some embodiments of the present invention;

FIG. 5 illustrates schematically partial of a TEM in accordance with one embodiment of the present invention where the insulating film is coupled to the surface of a vapor chamber;

FIG. 6 illustrates schematically partial of a TEM in accordance with one embodiment of the present invention where an insulating film is attached by soldering to a vapor chamber, not shown;

FIG. 7 illustrates schematically partial of a TEM in accordance with one embodiment of the present invention where an insulating film is attached by adhesion to a vapor chamber, not shown; and

FIG. 8 illustrates schematically partial of a TEM in accordance with one embodiment of the present invention where an insulating film attached to a vapor chamber by direct bonding technology.

The following detailed description of the invention refers to the accompanying drawings referred to above. Dimensions of components and features shown in the figures are chosen for convenience or clarity of presentation and are not necessarily shown to scale. Wherever possible, the same reference numbers will be used throughout the drawings and the following description to refer to the same and like parts.

### DETAILED DESCRIPTION OF EMBODIMENTS OF THE INVENTION

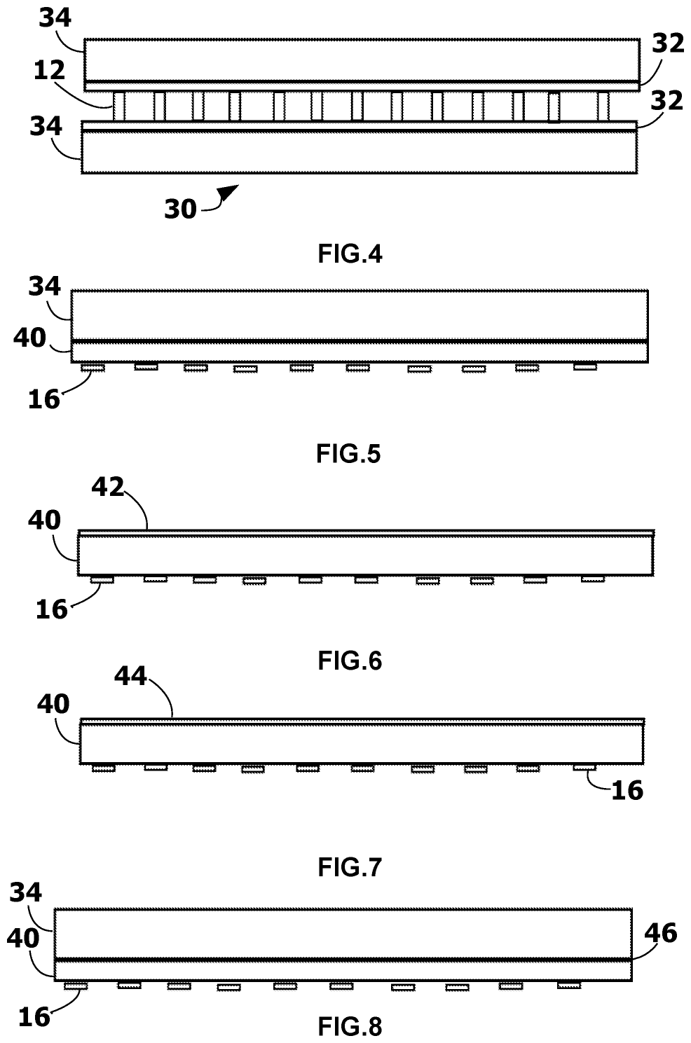

Referring to FIG. 4 there is shown a thermoelectric module (TEM) 30 in accordance with some embodiments of the present invention which can be used both for cooling and power generation. The TEM 30 includes thermoelectric legs 12 having conductors (not shown), one or more electrically insulated and thermally conductive films 32 and one or more vapor chambers 34. The thermoelectric legs 12 are connected in series through the conductors as known in the art. In accordance with some embodiments of the present invention, the thermoelectric legs are connected thermally in parallel in between two electrically insulated and thermally conductive films 32. The Conductors are made of suitable conducting material such as but not limited to copper. The electrically insulated and thermally conductive films 32 are operatively used for assembly of thermoelectric legs 12 on one or more vapor chambers 34 with minimal thermal losses. The one or more vapor chambers 34 are used as TEM substrates to be integrated for example with a cooling system. In accordance with the present invention the electrically insulated and thermally conductive films are required to prevent electric contact between the conductors of the thermoelectric legs and vapor chambers 34. The thickness of the electrically insulated and thermally conductive films has 15 to about 80 micron thicknesses which are much smaller in respect to TEM ceramic substrates as known in the art which their thicknesses are typically 200 to about 600 microns.

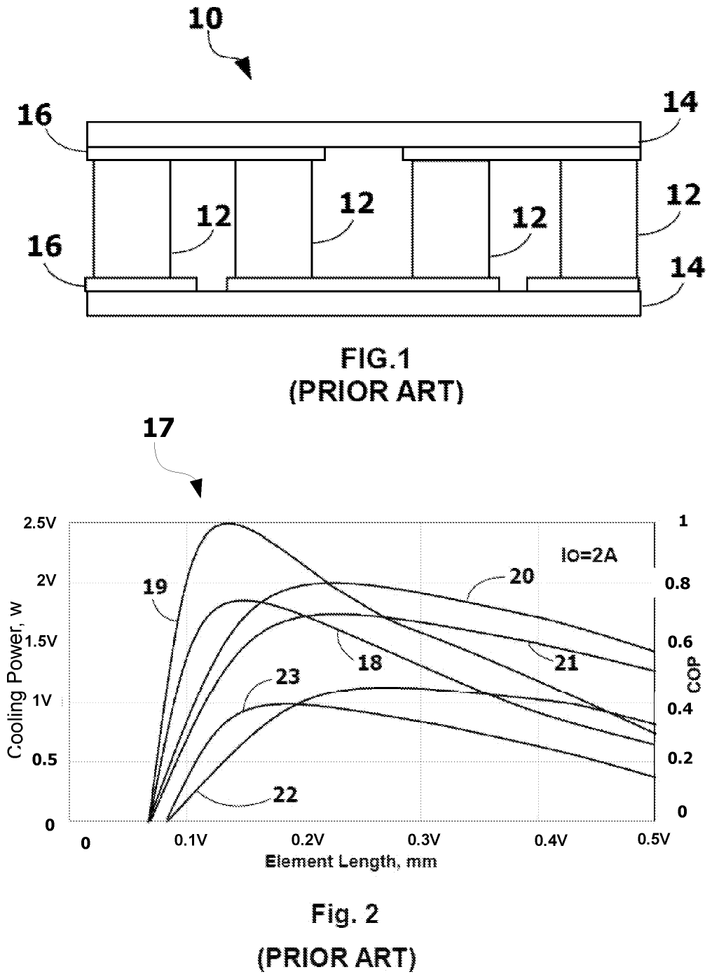

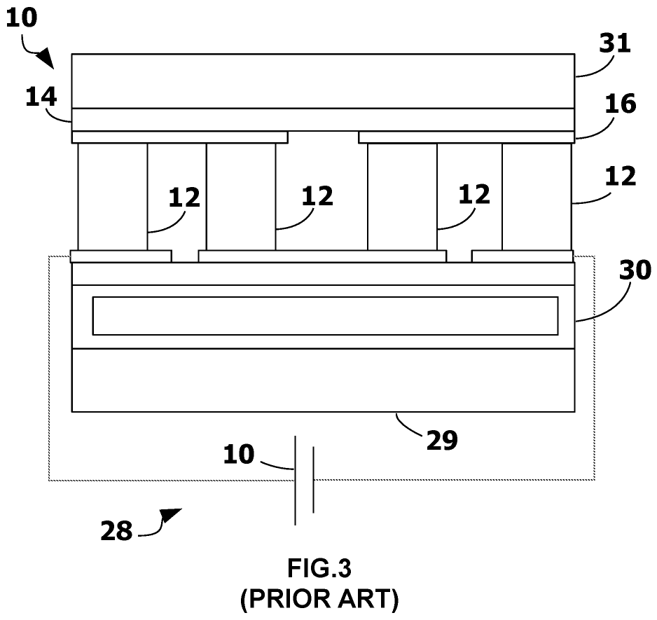

Vapor Chambers have effective thermal conductivity of 1,000-10,000 W/(m*K) which is 25 times higher than thermal conductivity of copper. Vapor chambers have a flat shape and can be made in the dimensions fitting substrates of thermoelectric modules. Thus, the use of vapor chambers 34 in accordance with the present invention improves performances such as cooling capacity, temperature difference and efficiency of the TEM 30 in respect to prior art ceramic plates 14 of TEM 20 that illustrated for example in FIG. 1.

The electrically insulating films 32 can be made for example from thin ceramic films such as but not limited to Zirconia, Alumina and aluminum nitride which are characterized by extremely low thickness and consequently low thermal resistance and low thermal mass. Such thin ceramic films are also characterized by a low mechanical strength which can be compensated by support of the vapor chambers 34. The vapor chambers 34 can be made from any suitable material preferably selected from copper, aluminum or titanium.

Referring to FIG. 5, in one embodiment of the present invention the outer surface of the vapor chamber 34, is coupled to the upper side of an electrically insulated and thermally conductive film 40 for example by oxidizing the vapor chamber outer surface. The bottom side of the electrically insulated and thermally conductive film 40 is coupled to the metal conductor pattern 16. Yet in another embodiment of the present invention the outer surface of the vapor chamber 34 can be coupled to electrically insulated and thermally conductive films 40 by coating the outer surface of the vapor chamber with electrically insolated ceramics material. Yet in other embodiments of the present invention the outer surface of the vapor chamber 34 can be used as electrically insulated and thermally conductive films 40 for example by bonding ceramics and metal by using explosion bonding of ceramic layer on the vapor chamber surface 34.

Referring to FIG. 6, in another embodiment of the present invention the electrically insulated and thermally conductive film 40 is coupled to the vapor chamber by soldering using solder capable to deal with mismatch of Coefficients of Thermal Expansion (CTE). Metallization layer 42 is coupled on the insulating and thermally conductive film 40 for vapor chamber soldering, not shown.

Referring to FIG. 7, in another embodiment of the present invention the electrically insulated and thermally conductive film 40 is attached to the outer surface of the vapor chamber, not shown, by adhesion using epoxy or silicone adhesives for creating an adhesive layer 44 capable to deal with mismatch of CTE.

Referring to FIG. 8, in another embodiment of the present invention Direct Copper or Aluminum Bonding Technology coupling means 46 designated in FIG. 7 by a thick straight line, is used to couple the electrically insulated and thermally conductive film 40 with the outer surface of the vapor chamber 34.

In accordance with some embodiments of the present invention the vapor chamber 34 and the insulated and thermally conductive film 40 are selected from copper, aluminum or titanium materials as one unit by using a 3D printer that prints with the aforementioned materials. In accordance with another embodiment of the present invention the insulated and thermally conductive film 40 is made by a 3D printing selected from a printed material of alumina, zirconia or AlN. In accordance with another embodiment of the present invention the vapor chamber 34 with the insulated and thermally conductive film are made as a unit by multilayer 3D printing of metal and ceramics.

It should be understood that the above description is merely exemplary and that there are various embodiments of the present invention that may be devised, mutatis mutandis, and that the features described in the above-described embodiments, and those not described herein, may be used separately or in any suitable combination; and the invention can be devised in accordance with embodiments not necessarily described above.

1-32. (canceled)

33. A thermoelectric module for cooling and power generation applications comprising:
a pair of thermally conductive substrates,
a plurality of electrically conductive contacts disposed on opposing faces of said pair of substrates; and
a plurality of thermoelectric legs interposed between said pair of substrates, each of said plurality of conductive contacts connecting thermoelectric legs to each other in series and
wherein, at least one of said thermally conductive substrate is a vapor chamber; and each of said thermoelectric legs has a first end connected to one of said conductive contacts of one of said substrates and a second end connected to one of said conductive contacts of the other of said substrates
thereby, said vaper chamber improves performances of cooling capacity, temperature difference and efficiency of said thermoelectric module.

34. A thermoelectric module according to claim 33, wherein said vapor chamber is made from a material selected from copper, aluminum and titanium.

35. A thermoelectric module according to claim 33, wherein said thermoelectric module further comprising electrically insulated and thermally conductive film between said vapor chamber.

36. A thermoelectric module according to claim 35, wherein said electrically insulated and thermally conductive films are made from a material selected from alumina, zirconia and aluminum nitride.

37. A thermoelectric module according to claim 35, wherein said electrically insulated and thermally conductive films are made by oxidizing surface of said vapor chamber.

38. A thermoelectric module according to claim 35, wherein said electrically insulated and thermally conductive films are coated on the surface of said vapor chamber.

39. A thermoelectric module according to claim 35, wherein said electrically insulated and thermally conductive films are made by explosion bonding of ceramic layer on the surface of said vapor chamber.

40. A thermoelectric module according to claim 36, wherein said insulated and thermally conductive films are coupled to said vapor chamber by soldering using solder capable to deal with mismatch of Coefficients of Thermal Expansion (CTE).

41. A thermoelectric module according to claim 33, wherein said insulated and thermally conductive films are coupled to said vapor chamber by adhesion using epoxy or silicone adhesives capable to deal with mismatch of CTE.

42. A thermoelectric module according to claim 36, wherein said insulated and thermally conductive films are coupled to said vapor chamber by Direct Copper Bonding Technology.

43. A thermoelectric module according to claim 35, wherein said electrically insulated and thermally conductive films has to about 80 micron thickness.

44. A thermoelectric module according to claim 36, wherein said insulated and thermally conductive films are coupled to said vapor chamber by Direct Aluminum Bonding Technology.

45. A thermoelectric module according to claim 34, wherein said vapor chamber and said insulating film are made as a one unit by a 3D printing selected from a printed material of copper, aluminum or titanium.

46. A thermoelectric module according to claim 35, wherein said insulating film is made by a 3D printing selected from a printed material of alumina, zirconia or AlN.

47. A thermoelectric module according to claim 34, wherein said vapor chamber with said insulating film are made as a unit by multilayer 3D printing of metal and ceramics.

48. A thermoelectric module according to claim 33 wherein said plurality of thermoelectric legs are a plurality of P-type and N-type thermoelectric elements interposed between said pair of substrates, each of said plurality of conductive contacts connecting adjacent P-type and N-type thermoelectric elements to each other in series and wherein each of said P-type and N-type elements has a first end connected to one of said conductive contacts of one of said substrates and a second end connected to one of said conductive contacts of the other of said substrates.

49. A method for forming a thermoelectric module (TEM) comprising the steps of:
coupling multiple thermoelectric legs to a pair of thermally conductive substrates such that the multiple thermoelectric legs are interposed between said pair of substrates;
coupling electrically conductive contacts to said pair of substrates that disposed on opposing faces of said pair of substrates; and
coupling electrically conductive contacts to said multiple thermoelectric legs so that the thermoelectric legs are connected to each other in series and each of said thermoelectric legs has a first end connected to one of said conductive contacts of one of said substrates and a second end connected to one of said conductive contacts of the other of said substrates,
wherein at least one substrate of said pair of thermally conductive substrates is a vapor chamber.

50. A method for forming a thermoelectric module (TEM) according to claim 49, wherein said vapor chamber is made from a material selected from copper, aluminum and titanium.

51. A method for forming a thermoelectric module (TEM) according to claim 49, wherein said thermoelectric module further coupling electrically insulated and thermally conductive films between said vapor chamber and said conductive contacts.

52. A method for forming a thermoelectric module (TEM) according to claim 51, wherein said electrically insulated and thermally conductive films are made from a material selected from alumina, zirconia and aluminum nitride.

53. A method for forming a thermoelectric module (TEM) according to claim 51, wherein said electrically insulated and thermally conductive films are made by oxidizing surface of said vapor chamber.

54. A method for forming a thermoelectric module (TEM) according to claim 51, wherein said electrically insulated and thermally conductive films are coated on the surface of said vapor chamber.

55. A method for forming a thermoelectric module (TEM) according to claim 51, wherein said electrically insulated and thermally conductive films are made by explosion bonding of ceramic layer on the surface of said vapor chamber.

56. A method for forming a thermoelectric module (TEM) according to claim 52, wherein said insulated and thermally conductive films are coupled to said vapor chamber by soldering using solder capable to deal with mismatch of Coefficients of Thermal Expansion (CTE).

57. A method for forming a thermoelectric module (TEM) according to claim 49, wherein said insulated and thermally conductive films are coupled to said vapor chamber by adhesion using epoxy or silicone adhesives capable to deal with mismatch of CTE.

58. A method for forming a thermoelectric module (TEM) according to claim 52, wherein said insulated and thermally conductive films are coupled to said vapor chamber by Direct Copper Bonding Technology.

59. A method for forming a thermoelectric module (TEM) according to claim 51, wherein said electrically insulated and thermally conductive films has 15 to about 30 micron thickness.

60. A method for forming a thermoelectric module (TEM) according to claim 52, wherein said insulated and thermally conductive films are coupled to said vapor chamber by Direct Aluminum Bonding Technology.

61. A method for forming a thermoelectric module (TEM) according to claim 60, wherein said vapor chamber and said insulating film are made as a one unit by a 3D printing selected from a printed material of copper, aluminum or titanium.

62. A method for forming a thermoelectric module (TEM) according to claim 61, wherein said insulating film is made by a 3D printing selected from a printed material of alumina, zirconia or AlN.

63. A method for forming a thermoelectric module (TEM) according to claim 49, wherein said vapor chamber with said insulating film are made as a unit by multilayer 3D printing of metal and ceramics.

64. A method for forming a thermoelectric module (TEM) according to claim 49, wherein said plurality of thermoelectric legs are a plurality of P-type and N-type thermoelectric elements interposed between said pair of substrates, each of said plurality of conductive contacts connecting adjacent P-type and N-type thermoelectric elements to each other in series and wherein each of said P-type and N-type elements has a first end connected to one of said conductive contacts of one of said substrates and a second end connected to one of said conductive contacts of the other of said substrates.
